(19) United States
(12) Patent Application Publication
(10) Pub. No.: US 2026/0068584 A1
(43) Pub. Date: Mar. 5, 2026

(54) APPARATUS FOR MANUFACTURING SEMICONDUCTOR PACKAGE AND METHOD OF MANUFACTURING SEMICONDUCTOR PACKAGE USING THE SAME

(71) Applicant: SAMSUNG ELECTRONICS CO., LTD., Suwon-si (KR)

(72) Inventors: SANGJINE PARK, Suwon-si (KR); Ji Hwan PARK, Suwon-si (KR)

(73) Assignee: SAMSUNG ELECTRONICS CO., LTD., Suwon-si (KR)

(21) Appl. No.: 19/061,296

(22) Filed: Feb. 24, 2025

(30) Foreign Application Priority Data
Aug. 29, 2024 (KR) 10-2024-0117132

(51) Int. Cl. H01L 21/67; H01L 21/56; H01L 21/66; H01L 21/683

(52) U.S. Cl. CPC H01L 21/67126

(57) ABSTRACT

An apparatus for manufacturing a semiconductor package is provided. The apparatus includes: a chuck configured to hold an object, wherein the object includes a wafer-to-wafer bonding structure, the wafer-to-wafer bonding structure includes an edge area, and a gap is defined in the edge area between wafers; and a supply structure configured to dispense a sealant toward the gap of the wafer-to-wafer bonding structure while held in a vertical orientation.

### CROSS-REFERENCE TO RELATED APPLICATION

This application claims priority to Korean Patent Application No. 10-2024-0117132, filed in the Korean Intellectual Property Office, on Aug. 29, 2024, the disclosure of which is incorporated herein in its entirety.

### BACKGROUND

### Field

The present disclosure relates to an apparatus for manufacturing a semiconductor package and a method of manufacturing a semiconductor package using the same.

### Description of Related Art

Semiconductor packages mounted in electronic devices are increasingly miniaturized, reduced in weight, and thinned while becoming faster, more versatile, and having higher capacities. To increase densities of mounted semiconductor chips included in the semiconductor packages, and shorten signal transmission paths and power transmission paths between the semiconductor chips, a wafer bonding process is used to implement a wafer-to-wafer bonding structure by bonding two wafers including the semiconductor chips during a process of manufacturing the semiconductor package.

The wafer-to-wafer bonding structure is manufactured by a process of forming a sealing layer on a bevel of each of the wafers and bonding the wafers having the sealing layer. Unless the sealing layer is formed on the bevel of each of the wafers, a gap is formed in a lateral side of the wafer-to-wafer bonding structure by the bevels of the wafers after the wafers are bonded, which may cause mechanical stress to be transmitted to the inside of the semiconductor chip or a chemical reaction solution may penetrate through the gap, which may damage circuits or lines in the semiconductor chip.

However, in case that the wafers are warped, positions of the bevels of the wafers may vary, and the sealing layers may not be formed at accurate positions on the bevels of the wafers even though the process of forming the sealing layers on the bevels of the wafers is performed. In addition, a chemical mechanical polishing (CMP) process is performed to planarize the sealing layer after the sealing layer is formed on the bevel of each of the wafers, but the sealing layer may be damaged by a CMP pad during the CMP process. When the sealing layer is damaged, the wafer may be chipped, and mechanical stress may be transmitted to the inside of the semiconductor chip or a chemical reaction solution may penetrate through a chipped space as if no sealing layer is formed on the bevel of the wafer. For this reason, the circuits or the lines in the semiconductor chip may be damaged.

### SUMMARY

One or more embodiments provide a method and apparatus for covering a gap formed between wafers of a wafer-to-wafer bonding structure.

According to an aspect of an embodiment, an apparatus for manufacturing a semiconductor package, includes: a chuck configured to hold an object, wherein the object includes a wafer-to-wafer bonding structure, the wafer-to-wafer bonding structure includes an edge area, and a gap is defined in the edge area between wafers; and a supply structure configured to dispense a sealant toward the gap of the wafer-to-wafer bonding structure while held in a vertical orientation.

According to another aspect of an embodiment, an apparatus for manufacturing a semiconductor package, includes: a chuck configured to support an object in a horizontal orientation and in a vertical orientation, apply suction to hold the object while in the vertical orientation, and rotate the object while in the vertical orientation, wherein the object includes a wafer-to-wafer bonding structure, the wafer-to-wafer bonding structure includes an edge area, and a gap is defined in the edge area between wafers; and a supply structure configured to dispense a sealant to the gap of the wafer-to-wafer bonding structure held in the vertical orientation. The supply structure includes: a heating device configured to apply heat to the sealant on the wafer-to-wafer bonding structure while held in the vertical orientation; a shaping device configured to apply pressure to the sealant on the wafer-to-wafer bonding structure while held in the vertical orientation; and a cooling device configured to cool the sealant on the wafer-to-wafer bonding structure while held in the vertical orientation.

According to another aspect of an embodiment, a method of manufacturing a semiconductor package, includes: applying suction to hold a wafer-to-wafer bonding structure in a vertical orientation, wherein the wafer-to-wafer bonding structure includes an edge area, and a gap is defined in the edge area between wafers; and filling the gap of the wafer-to-wafer bonding structure with a sealant while in the vertical orientation.

The position of the gap of the wafer-to-wafer bonding structure held in the vertical direction may be measured, and the gap may be covered by the sealing part, such that the sealing part may be formed at an accurate position regardless of whether the wafer is warped.

Whether a defect is present in the sealing part may be determined, and the defect in the sealing part may be eliminated by shaping the sealing part, which may prevent mechanical stress from being transmitted to the inside of the semiconductor chip or prevent the chemical reaction solution from penetrating into the semiconductor chip through the sealing part having no defect.

### BRIEF DESCRIPTION OF DRAWINGS

The above and other aspects will be more apparent from the following description of embodiments, taken in conjunction with the accompanying drawings, in which:

FIG. 1 is a perspective view illustrating an apparatus for manufacturing a semiconductor package of an embodiment.

FIG. 2 is a cross-sectional view illustrating a wafer-to-wafer bonding structure of an embodiment.

FIG. 3 is a cross-sectional view illustrating a chuck and a wafer-to-wafer bonding structure in a horizontal direction according to an embodiment.

FIG. 4 is a perspective view illustrating a supply structure of an embodiment.

FIG. 5 is a cross-sectional view illustrating a supply structure of an embodiment.

FIG. 6 is a cross-sectional view illustrating the supply structure of an embodiment.

FIG. 7 is a cross-sectional view illustrating the supply structure of an embodiment.

FIG. 8 is a perspective view illustrating the apparatus for manufacturing a semiconductor package in which the supply structure is aligned on the wafer-to-wafer bonding structure held in a vertical direction according to an embodiment.

FIGS. 9 to 16 are cross-sectional views illustrating a method of manufacturing a semiconductor package of an embodiment.

### DETAILED DESCRIPTION

Hereinafter, embodiments are described in detail with reference to the accompanying drawings. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure.

In the drawings, a part irrelevant to the description may be omitted to clearly describe the present disclosure, and the same or similar constituent elements will be designated by the same reference numerals throughout the specification.

In addition, a size and thickness of each constituent element illustrated in the drawings are shown for convenience of description, but embodiments are not limited thereto.

It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present.

In addition, throughout the specification, the phrase “in a plan view” indicates an object is viewed from above, and the phrase “in a cross-sectional view” indicates a cross section made by vertically cutting an object viewed from a lateral side.

Hereinafter, an apparatus 10 for manufacturing a semiconductor package and a method of manufacturing a semiconductor package of an embodiment will be described with reference to the drawings.

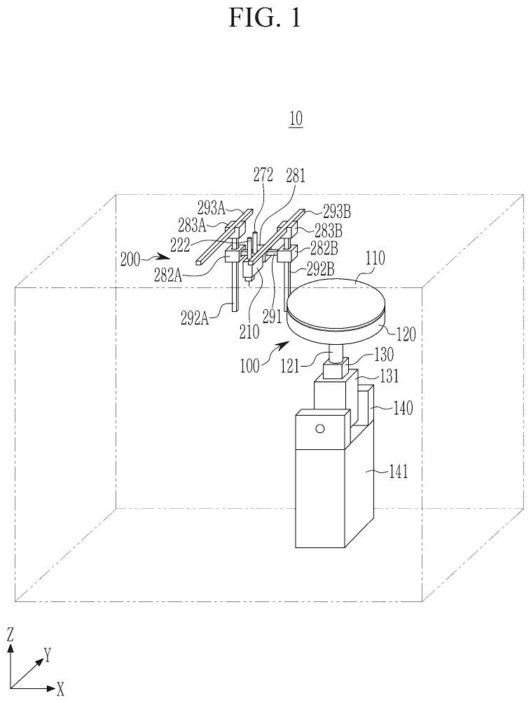

FIG. 1 is a cross-sectional view illustrating the apparatus 10 for manufacturing a semiconductor package of an embodiment.

With reference to FIG. 1, the apparatus 10 for manufacturing a semiconductor package may include a mounting structure 100 and a sealing member supply structure 200.

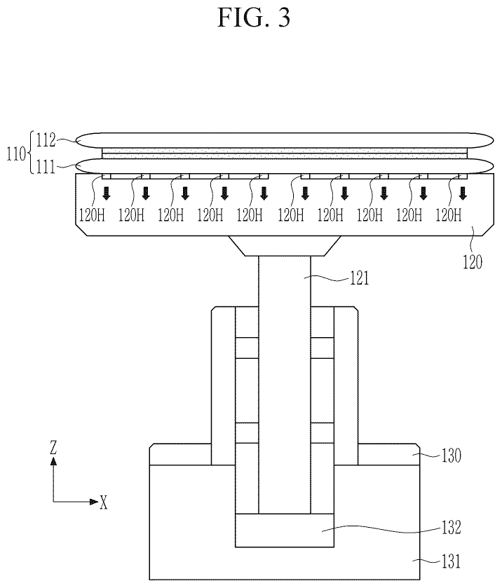

The mounting structure 100 may include a chuck 120 configured to hold an object, a rotary rod 121, a bearing 130, an actuator 131, a motor 132 (see FIG. 3), a guide structure 140, and a mount 141.

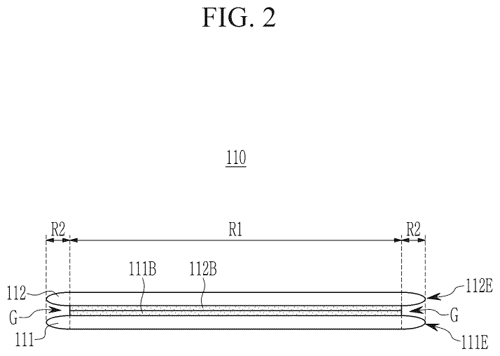

The object may be positioned on the chuck 120. The object may include a wafer-to-wafer bonding structure 110. FIG. 2 is a cross-sectional view illustrating the wafer-to-wafer bonding structure 110 of an embodiment.

With reference to FIGS. 1 and 2, the wafer-to-wafer bonding structure 110 may be formed by bonding a first wafer 111, which has no sealing layer, and a second wafer 112 having no sealing layer. The wafer-to-wafer bonding structure 110 may include the first wafer 111, the second wafer 112, a first structure 111B, and a second structure 112B.

The first wafer 111 and the second wafer 112 may be bonded to each other to define a single structure. The second wafer 112 may be positioned such that a front side of the second wafer 112 faces a front side of the first wafer 111, or the second wafer 112 may be positioned such that a back side of the second wafer 112 faces the front side of the first wafer 111. Alternatively, the second wafer 112 may be positioned such that the front side of the second wafer 112 faces a back side of the first wafer 111, or the second wafer 112 may be positioned such that the back side of the second wafer 112 faces the back side of the first wafer 111. In an embodiment, the first wafer 111 and the second wafer 112 may each include a device wafer having integrated circuits and lines. In an embodiment, the first wafer 111 may include a carrier wafer.

The first wafer 111 and the second wafer 112 may each include a device area R1 and an edge area R2. The device area R1 may include the integrated circuits and the lines. In a plan view, the edge area R2 may include a ring shape that surrounds the device area R1. The edge area R2 of the first wafer 111 may be a bevel of the first wafer 111. No sealing layer may be formed in the edge area R2 of the first wafer 111. The edge area R2 of the second wafer 112 may be a bevel of the second wafer 112. No sealing layer may be formed in the edge area R2 of the second wafer 112.

The first structure 111B may be positioned on the front or back side of the first wafer 111. The second structure 112B may be positioned on the front or back side of the second wafer 112. The first structure 111B and the second structure 112B may be bonded to each other by hybrid copper bonding. The first structure 111B and the second structure 112B may each include at least one of an element structure, a wiring structure, and a bonding structure. In an embodiment, the first structure 111B and the second structure 112B may each be formed in the device area R1. In an embodiment, the first structure 111B and the second structure 112B may each extend from the device area R1 to the edge area R2. For example, the first structure 111B may be formed to extend from the device area R1 to the edge area R2, and the first structure 111B may have a rounded shape along the bevel of the first wafer 111 in the edge area R2. For example, the second structure 112B may be formed to extend from the device area R1 to the edge area R2, and the second structure 112B may have a rounded shape along the bevel of the second wafer 112 in the edge area R2.

The wafer-to-wafer bonding structure 110 may include a gap G in the edge area R2. The gap G may be formed by a shape of the bevel of the first wafer 111 and a shape of the bevel of the second wafer 112. The gap G may be formed between the bevel of the first wafer 111 and the bevel of the second wafer 112. The gap G may have a shape recessed based on an edge 111E of the first wafer 111 and an edge 112E of the second wafer 112.

With reference back to FIG. 1, the chuck 120 may support and hold the wafer-to-wafer bonding structure 110. FIG. 3 is a cross-sectional view illustrating the chuck 120 and the wafer-to-wafer bonding structure 110 in a first horizontal direction (X direction).

With reference to FIGS. 1 and 3, the chuck 120 includes a first surface on which the wafer-to-wafer bonding structure 110 may be disposed. The chuck 120 may be disposed such that the first surface extends in the first horizontal direction (X direction) and a second horizontal direction (Y direction). The chuck 120 may accommodate and support the wafer-to-wafer bonding structure 110.

The chuck 120 may hold the wafer-to-wafer bonding structure 110 on the first surface so that the wafer-to-wafer bonding structure 110 does not depart from the chuck 120. The first surface of the chuck 120 may include vacuum suction openings 120H. The vacuum suction openings 120H may hold the wafer-to-wafer bonding structure 110 on the first surface of the chuck 120 by vacuum-sucking the wafer-to-wafer bonding structure 110. The vacuum suction openings 120H may be connected to an external vacuum. When a vacuum is applied by the vacuum, the vacuum suction openings 120H may hold the wafer-to-wafer bonding structure 110 on the chuck 120 by sucking the wafer-to-wafer bonding structure 110. When the vacuum is removed by the vacuum, the vacuum suction openings 120H may release the wafer-to-wafer bonding structure 110.

The rotary rod 121 may be positioned on a second surface of the chuck 120 opposite to the first surface. The rotary rod 121 may be integrated with the chuck 120. One end of the rotary rod 121 may be coupled to the motor 132, and the other end of the rotary rod 121 may be coupled to the chuck 120. The rotary rod 121 may be rotated by the motor 132.

The bearing 130 may be disposed to surround the rotary rod 121. The bearing 130 may fix a shaft of the rotary rod 121 at a predetermined position and cover one surface of the actuator 131.

The actuator 131 may perform a reciprocating motion in a direction perpendicular to the first surface of the chuck 120. The chuck 120 may be moved in a vertical direction (Z direction) perpendicular to the first surface of the chuck 120 by a movement of the actuator 131.

The motor 132 may be disposed in the actuator 131. The motor 132 may be coupled to the rotary rod 121, and may rotate the rotary rod 121 and the chuck 120 coupled to the rotary rod 121. The chuck 120 may rotate the wafer-to-wafer bonding structure 110.

With reference back to FIG. 1, the guide structure 140 may be disposed on the mount 141. The guide structure 140 may accommodate the actuator 131. The guide structure 140 may support the actuator 131 in the vertical direction (Z direction) and fix the actuator 131. The guide structure 140 may support the actuator 131 in the first horizontal direction (X direction) and fix the actuator 131. The guide structure 140 may include a guide opening that enables the actuator 131 to move between the first horizontal direction (X direction) and the vertical direction (Z direction). The guide structure 140 may guide the actuator 131 and prevent the actuator 131 from moving in another direction so that the actuator 131 may move between the first horizontal direction (X direction) and the vertical direction (Z direction).

The mount 141 may fix the mounting structure 100 to a predetermined position in the apparatus 10 for manufacturing a semiconductor package. The mount 141 may move the mounting structure 100 in the first horizontal direction (X direction), the second horizontal direction (Y direction), and the vertical direction (Z direction).

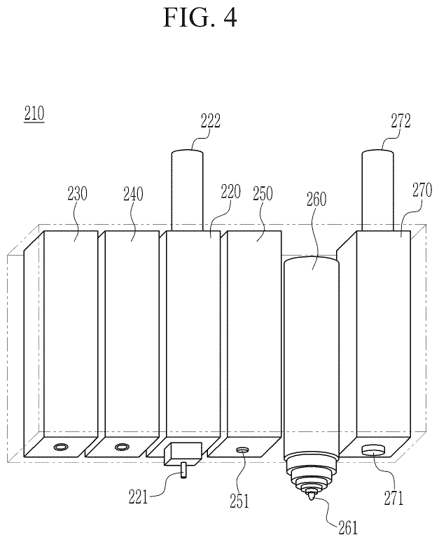

The sealing member supply structure 200 may include a supply structure 210, a transfer structure 280, and a guide rail 290. FIG. 4 is a perspective view illustrating the supply structure 210 of an embodiment.

With reference to FIGS. 1 and 4, the supply structure 210 may include a supply structure 220, a position sensor 230, an optical sensor 240, a heating device 250, a shaping device 260, and a cooling device 270. The supply structure 220, the position sensor 230, the optical sensor 240, the heating device 250, the shaping device 260, and the cooling device 270 may all be disposed in a single housing or disposed in separate housings.

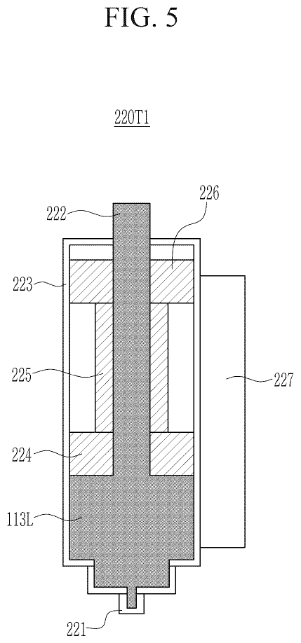

The supply structure 220 may store a sealing member (i.e., sealant) 113L. The supply structure 220 may inject the sealing member 113L into the wafer-to-wafer bonding structure 110. In an embodiment, the sealing member 113L may include an organic material. In an embodiment, the sealing member 113L may include a polymer including an inorganic filler. In an embodiment, the inorganic filler may include silica. In an embodiment, the polymer may include epoxy resin. FIGS. 5 to 7 are cross-sectional views each illustrating the supply structure of an embodiment.

With reference to FIGS. 4 and 5, the supply structure 220T1 may supply (i.e., dispense) the sealing member 113L discontinuously. The supply structure 220T1 may include a syringe shape. The supply structure 220T1 may include a nozzle 221, a supply line 222, a cylinder 223, a plunger 224, a rod 225, a cap 226, and a heater 227. The nozzle 221 may extend from the cylinder 223. The nozzle 221 may discharge the sealing member 113L. The supply line 222 is a line through which the sealing member 113L is supplied into the cylinder 223 from an external storage tank. The supply line 222 may penetrate the plunger 224, the rod 225, and the cap 226. The supply line 222 may further include at least one of a controller, a valve, a flowmeter, and a sensor. The cylinder 223 may include the plunger 224, the rod 225, and the cap 226 therein. The cylinder 223 may accommodate the sealing member 113L between the nozzle 221 and the plunger 224. The plunger 224 may be positioned on an upper surface of the sealing member 113L. The rod 225 may be disposed on the plunger 224. The rod 225 may transmit pressure, which is transmitted to the cap 226, to the plunger 224. The cap 226 may cover the inside of the cylinder 223 from the outside and transmit pressure to the rod 225 from the actuator connected to the supply structure 220T1. The heater 227 may be disposed outside the cylinder 223. The heater 227 may maintain the sealing member 113L in a liquid state. In an embodiment, the heater 227 may maintain a temperature of the sealing member 113L at about 150° C. to about 450° C.

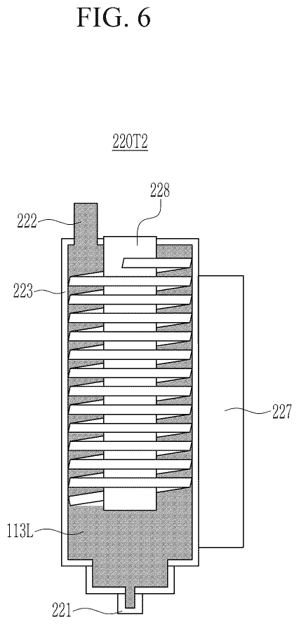

With reference to FIGS. 4 and 6, the supply structure 220T2 may supply the sealing member 113L continuously. The supply structure 220T2 may include a screw shape. The supply structure 220T2 may include the nozzle 221, the supply line 222, the cylinder 223, the heater 227, and a screw 228. The nozzle 221 may extend from the cylinder 223. The nozzle 221 may discharge the sealing member 113L. The supply line 222 is a line through which the sealing member 113L is supplied into the cylinder 223 from the external storage tank. The supply line 222 may further include at least one of a controller, a valve, a flowmeter, and a sensor. The cylinder 223 may include the screw 228 therein. The cylinder 223 may accommodate the sealing member 113L therein. The heater 227 may be disposed outside the cylinder 223. The heater 227 may maintain the sealing member 113L in a liquid state. In an embodiment, the heater 227 may maintain a temperature of the sealing member 113L at about 150° C. to about 450° C. The screw 228 may rotate to push the sealing member 113L toward the nozzle 221.

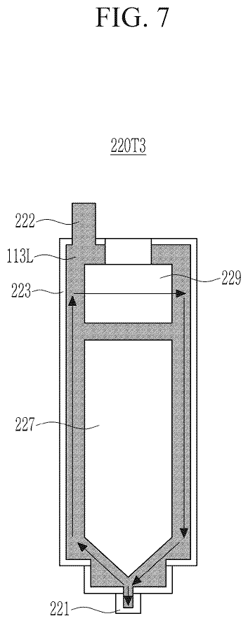

With reference to FIGS. 4 and 7, the supply structure 220T3 may supply the sealing member 113L continuously. The supply structure 220T3 may include a circulator shape. The supply structure 220T3 may include the nozzle 221, the supply line 222, the cylinder 223, the heater 227, and a circulator 229. The nozzle 221 may extend from the cylinder 223. The nozzle 221 may discharge the sealing member 113L. The supply line 222 is a line through which the sealing member 113L is supplied into the cylinder 223 from the external storage tank. The supply line 222 may further include at least one of a controller, a valve, a flowmeter, and a sensor. The cylinder 223 may include the heater 227 and the circulator 229 therein. The cylinder 223 may accommodate the sealing member 113L therein. The heater 227 may be disposed in the cylinder 223. The heater 227, together with the cylinder 223, may define a path through which the sealing member 113L flows. The heater 227 may maintain the sealing member 113L in a liquid state. In an embodiment, the heater 227 may maintain a temperature of the sealing member 113L at about 150° C. to about 450° C. The circulator 229 may circulate the sealing member 113L. The sealing member 113L may be circulated by the circulator 229 along the path defined by the cylinder 223 and the heater 227, and the sealing member 113L may be discharged to the outside through the nozzle 221.

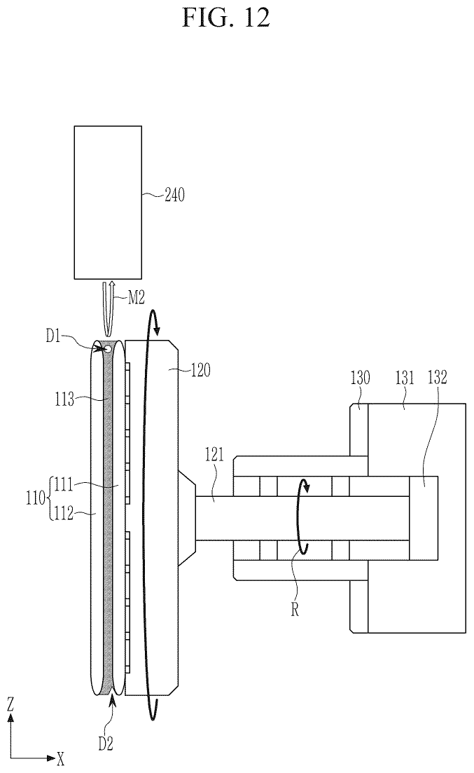

With reference back to FIG. 4, the position sensor 230 may measure a position of the wafer-to-wafer bonding structure 110. The optical sensor 240 may detect a defect occurring in a sealing part 113 (see FIG. 12) of the wafer-to-wafer bonding structure 110.

In case that it is necessary to shape the sealing part 113 cured on the wafer-to-wafer bonding structure 110, the heating device 250 may convert the sealing part 113 into the sealing member 113L in the liquid state by heating the sealing part 113 cured on the wafer-to-wafer bonding structure 110. In an embodiment, the heating device 250 may include a laser. The heating device 250 may include a laser emitting part 251 and emit laser beams to the sealing part 113 by means of the laser emitting part 251. In an embodiment, the heating device 250 may apply heat to the cured sealing part 113 to melt the cured sealing part 113 into the sealing member 113L in the liquid state having a temperature of about 150° C. to about 450° C.

The shaping device 260 may be used to shape the sealing member 113L melted by the heating device 250. The shaping device 260 may apply pressure directly to the sealing member 113L on the wafer-to-wafer bonding structure 110. The shaping device 260 may include a forming part 261 for shaping the sealing member 113L. In an embodiment, the forming part 261 may have a conical shape or a truncated conical shape. In an embodiment, a portion of the forming part 261, which is in contact with the sealing member 113L, may have a flat shape or a rounded shape. In an embodiment, the forming part 261 may include a heat-resistant ceramic or a metallic material with a high melting point.

The cooling device 270 may cool the sealing member 113L on the wafer-to-wafer bonding structure 110. The cooling device 270 may include a fluid discharge port 271 and a supply line 272. In an embodiment, the cooling device 270 may cool the sealing member 113L in a high-temperature liquid state to a room temperature. The sealing member 113L in the liquid state may become the cured sealing part 113 by being cooled. In an embodiment, the cooling device 270 may use air or deionized (DI) water as a cooling fluid. The fluid discharge port 271 may discharge the cooling fluid. The supply line 272 is a line through which the cooling fluid is supplied into the cooling device 270 from an external storage tank. The supply line 272 may further include at least one of a controller, a valve, a flowmeter, and a sensor.

With reference back to FIG. 1, the transfer structure 280 may be supported by the guide rail 290. The transfer structure 280 may move along the guide rail 290. The transfer structure 280 may include a first movement part 281, second movement parts 282 (282A and 282B), and third movement parts 283 (283A and 283B). The guide rail 290 may be disposed along a path along which the transfer structure 280 moves, and the guide rail 290 may guide the transfer structure 280. The guide rail 290 may include a first guide rail 291, second guide rails 292 (292A and 292B), and third guide rails 293 (293A and 293B).

The first movement part 281 may be disposed on the first guide rail 291. The first movement part 281 may move in the first horizontal direction (X direction) along the first guide rail 291. The first movement part 281 may move the supply structure 210 in the first horizontal direction (X direction). The first guide rail 291 may extend in the first horizontal direction (X direction). The second movement parts 282A and 282B may be respectively disposed on the second guide rails 292A and 292B. The second movement parts 282A and 282B may move in the vertical direction (Z direction) along the second guide rails 292A and 292B, respectively. The second movement parts 282A and 282B may move the supply structure 210 in the vertical direction (Z direction). The second guide rails 292A and 292B may extend in the vertical direction (Z direction). The third movement parts 283A and 283B may be respectively disposed on the third guide rails 293A and 293B. The third movement parts 283A and 283B may move in the second horizontal direction (Y direction) along the third guide rails 293A and 293B, respectively. The third movement parts 283A and 283B may move the supply structure 210 in the second horizontal direction (Y direction). The third guide rails 293A and 293B may extend in the second horizontal direction (Y direction).

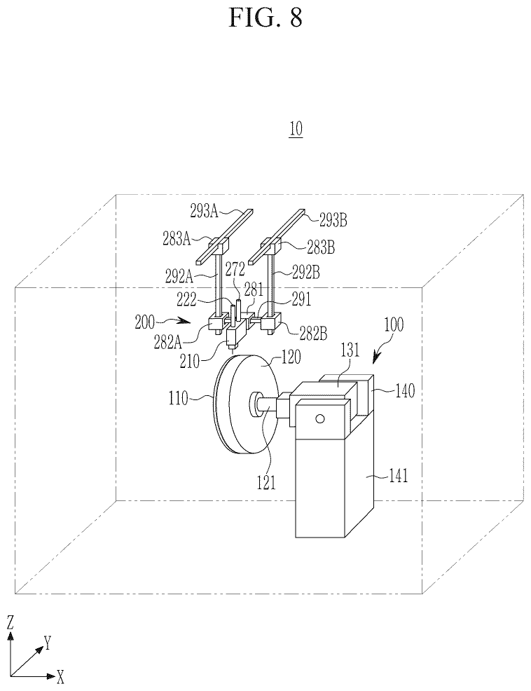

FIG. 8 is a perspective view illustrating the apparatus 10 for manufacturing a semiconductor package in which the supply structure 210 is aligned on the wafer-to-wafer bonding structure 110 held in the vertical direction according to an embodiment.

With reference to FIG. 8, the actuator 131, which stands in the vertical direction (Z direction) in FIG. 1, may be moved to be laid in the first horizontal direction (X direction) by the guide structure 140. The chuck 120 may be moved by the movement of the actuator 131 so that the first surface of the chuck 120 is directed in the first horizontal direction (X direction). The chuck 120 may continue to vacuum-suck the wafer-to-wafer bonding structure 110 while moving. After the movement of the chuck 120 is ended, the chuck 120 may hold the wafer-to-wafer bonding structure 110, which is vacuum-sucked by the chuck 120, in the vertical direction. The supply structure 210 may be moved to the wafer-to-wafer bonding structure 110 held in the vertical direction (Z direction), and the supply structure 210 may be aligned on the wafer-to-wafer bonding structure 110.

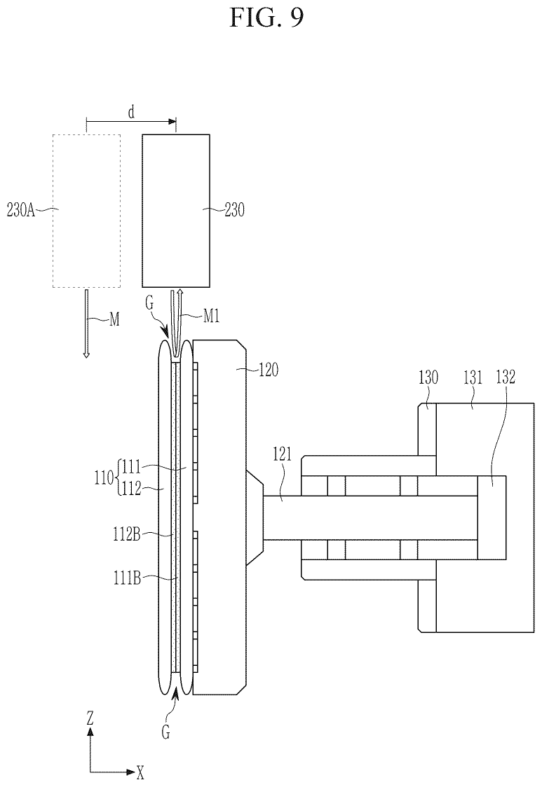

FIGS. 9 to 16 are cross-sectional views illustrating a method of forming the sealing part 113 in the wafer-to-wafer bonding structure 110.

FIG. 9 is a cross-sectional view illustrating an operation of measuring (M1) a position of the wafer-to-wafer bonding structure 110 by using the position sensor 230.

With reference to FIG. 9, the position sensor 230 may measure (M1) a position of the gap G of the wafer-to-wafer bonding structure 110. In case that the measurement result (M) of the position sensor 230 indicates that the position sensor 230 cannot find the gap G of the wafer-to-wafer bonding structure 110 (see the position sensor 230A indicated by the dotted line), the transfer structure 280 may be used to move the position sensor 230 (or the supply structure 210) in the horizontal direction (X direction or Y direction). As shown, the position sensor 230 may be moved distance d in the horizontal direction X. In case that the measurement result (M) of the position sensor 230 indicates that the position sensor 230 finds the gap G of the wafer-to-wafer bonding structure 110, the position sensor 230 (or the supply structure 210) may stop moving at a position aligned with the gap G of the wafer-to-wafer bonding structure 110.

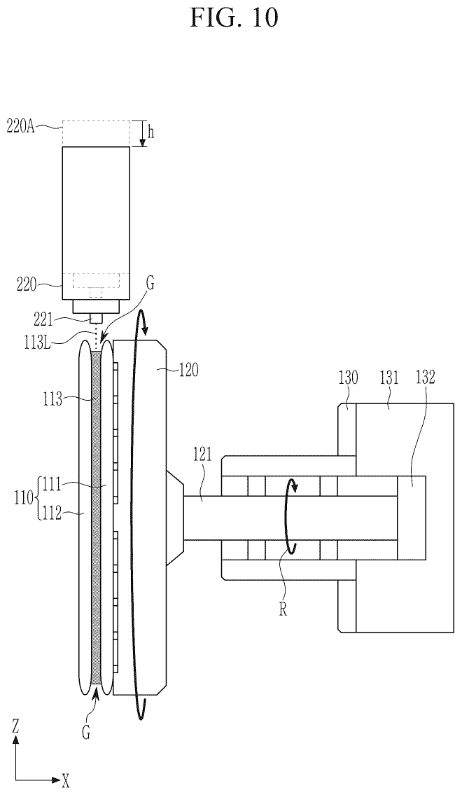

FIG. 10 is a cross-sectional view illustrating an operation of forming the sealing part 113 in the gap G of the wafer-to-wafer bonding structure 110 by using the supply structure 220.

With reference to FIG. 10, the transfer structure 280 may be used to move (h) the supply structure (see the supply structure 220A indicated by the dotted line) in the vertical direction (Z direction) to a position at which the supply structure 220 may inject the sealing member 113L into the gap G of the wafer-to-wafer bonding structure 110. As shown, the supply structure 220A may be moved by distance h in the vertical direction Z.

Thereafter, the motor 132 may operate to rotate the rotary rod 121, the chuck 120, and the wafer-to-wafer bonding structure 110 sucked by the chuck 120.

Thereafter, the sealing member 113L may be injected into the gap G of the rotating wafer-to-wafer bonding structure 110 from the supply structure 220. The supply structure 220 may discharge the sealing member 113L through the nozzle 221.

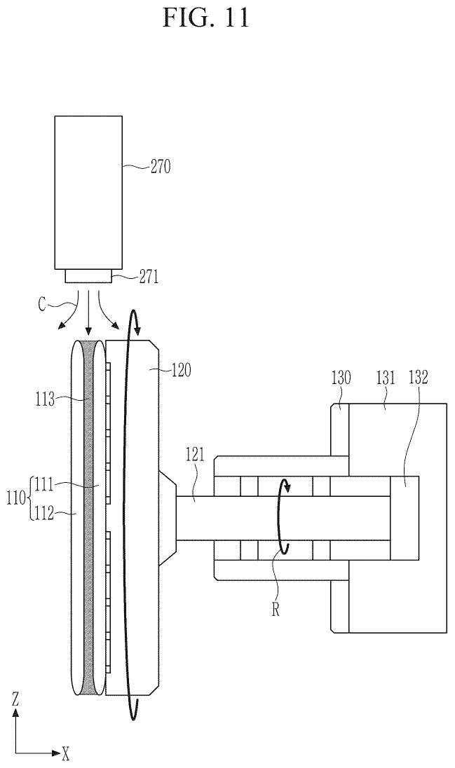

FIG. 11 is a cross-sectional view illustrating an operation of cooling the sealing part 113 by using the cooling device 270.

With reference to FIG. 11, the cooling device 270 may be used to cool the sealing member 113L in the gap G of the wafer-to-wafer bonding structure 110. The cooling device 270 may spray the cooling fluid toward the sealing member 113L in the gap G of the rotating wafer-to-wafer bonding structure 110. The cooling device 270 may spray the fluid through the fluid discharge port 271. The cooling device 270 may cool the sealing member 113L until a temperature of the sealing member 113L reaches a room temperature, such that the sealing part 113 may be formed.

FIG. 12 is a cross-sectional view illustrating an operation of inspecting (M2) the wafer-to-wafer bonding structure 110 by using the optical sensor 240 to identify a defect of the sealing part 113.

With reference to FIG. 12, the optical sensor 240 may be used to inspect (M2) whether the sealing part 113 of the wafer-to-wafer bonding structure 110 is defective (i.e., whether the sealing part 113 includes a defect). The optical sensor 240 may inspect (M2) the wafer-to-wafer bonding structure 110 to determine whether a void is present in the sealing part 113 (D1) or whether the sealing part 113 has a thickness of a threshold value or more (D2). The optical sensor 240 may perform the inspection (M2) on the stationary wafer-to-wafer bonding structure 110 or the rotating wafer-to-wafer bonding structure 110.

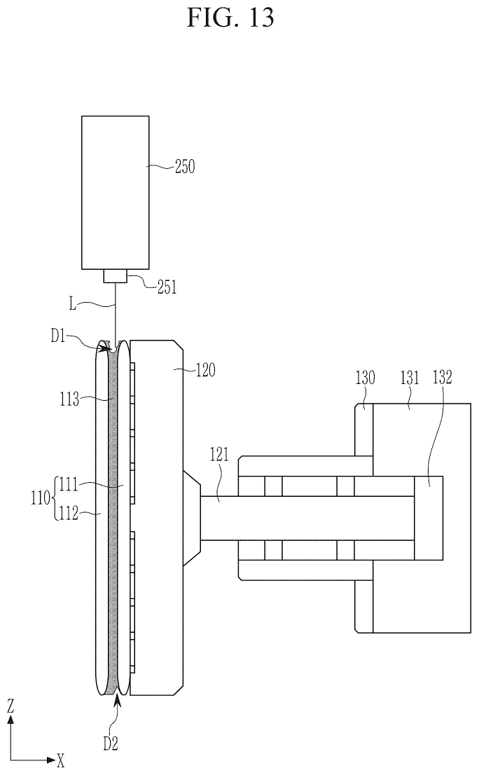

FIG. 13 is a cross-sectional view illustrating an operation of heating a periphery of the defective sealing part 113 by using the heating device 250.

With reference to FIG. 13, in case that the sealing part 113 is determined as being defective, a periphery of a position determined as having a defect of the sealing part 113 may be heated by the heating device 250. The heating device 250 may heat the stationary wafer-to-wafer bonding structure 110. The heating device 250 may emit laser beams L to the cured sealing part 113. The cured sealing part 113 may be melted into the liquid sealing member 113L by the laser beams L. The void in the sealing part 113 may be exposed to the outside by the laser beams L.

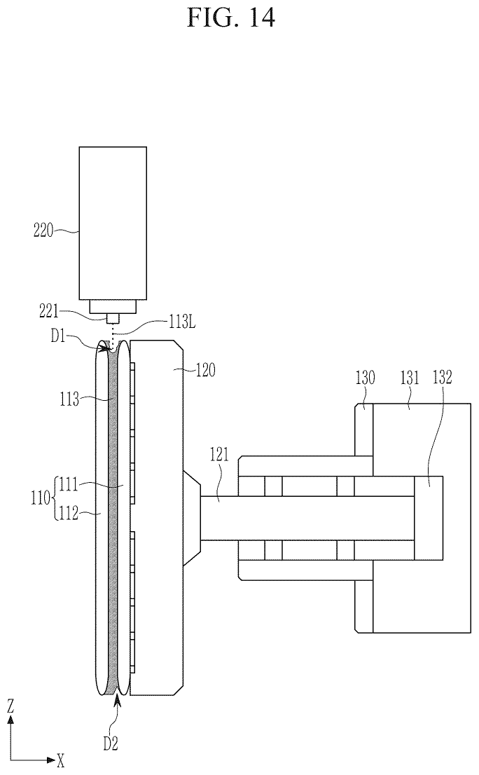

FIG. 14 is a cross-sectional view illustrating an operation of injecting the sealing member 113L to the defect of the wafer-to-wafer bonding structure 110 by using the supply structure 220.

With reference to FIG. 14, the supply structure 220 may be used to additionally inject the sealing member 113L into the position determined as being defective and then heated. The supply structure 220 may inject the sealing member 113L into the stationary wafer-to-wafer bonding structure 110. The supply structure 220 may discharge the sealing member 113L through the nozzle 221.

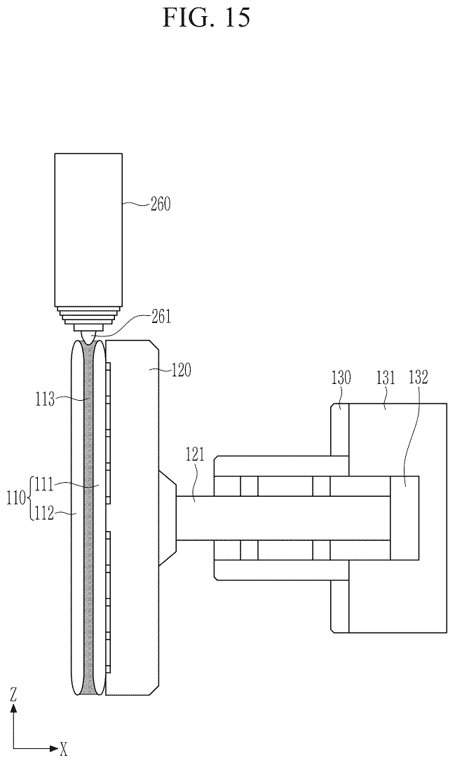

FIG. 15 is a cross-sectional view illustrating an operation of shaping the sealing member 113L of the wafer-to-wafer bonding structure 110 by using the shaping device 260.

With reference to FIG. 15, the shaping device 260 may be used to apply pressure to the additionally injected sealing member 113L on the wafer-to-wafer bonding structure 110. By the shaping process, density and firmness of the sealing part 113 of the wafer-to-wafer bonding structure 110 may increase, and the defect in the sealing part 113 may be eliminated.

According to embodiments, the gap G of the edge area R2 of the wafer-to-wafer bonding structure 110 may be covered by the sealing part 113 having no defect. Therefore, it is possible to prevent mechanical stress applied to the lateral side of the wafer-to-wafer bonding structure 110 from being transmitted to the inside of the semiconductor chip and to prevent the chemical reaction solution from penetrating into the lateral side of the wafer-to-wafer bonding structure 110.

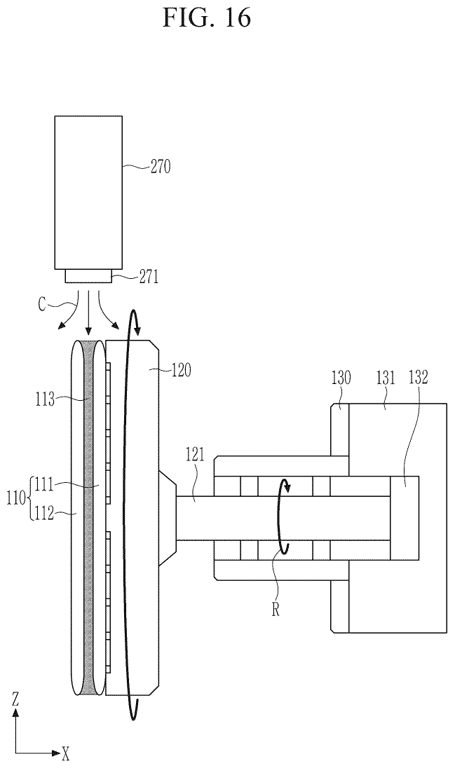

FIG. 16 is a cross-sectional view illustrating an operation of cooling the sealing member 113L by using the cooling device 270.

With reference to FIG. 16, the cooling device 270 may be used to cool the sealing member 113L of the wafer-to-wafer bonding structure 110. The cooling device 270 may spray the cooling fluid toward the sealing member 113L of the rotating wafer-to-wafer bonding structure 110. The cooling device 270 may spray the fluid through the fluid discharge port 271. The cooling device 270 may cool the sealing member 113L until the temperature of the sealing member 113L becomes the room temperature.

While aspects of embodiments have been particularly shown and described, it will be understood that various changes in form and details may be made therein without departing from the spirit and scope of the following claims.

What is claimed is:

1. An apparatus for manufacturing a semiconductor package, the apparatus comprising:
a chuck configured to hold an object, wherein the object comprises a wafer-to-wafer bonding structure, the wafer-to-wafer bonding structure comprises an edge area, and a gap is defined in the edge area between wafers; and
a supply structure configured to dispense a sealant toward the gap of the wafer-to-wafer bonding structure while held in a vertical orientation.

2. The apparatus of claim 1, wherein the supply structure is further configured to discontinuously dispense the sealant.

3. The apparatus of claim 1, wherein the supply structure comprises:
a cylinder accommodating the sealant;
a nozzle extending from the cylinder;
a plunger in the cylinder and on an upper surface of the sealant; and
a supply line configured to supply the sealant into the cylinder.

4. The apparatus of claim 1, wherein the supply structure is further configured to continuously dispense the sealant.

5. The apparatus of claim 1, wherein the supply structure comprises:
a cylinder accommodating the sealant;
a nozzle extending from the cylinder;
a screw provided in the cylinder; and
a supply line configured to supply the sealant into the cylinder.

6. The apparatus of claim 1, wherein the supply structure comprises:
a cylinder accommodating the sealant;
a nozzle extending from the cylinder;
a circulator in the cylinder;
a heater in the cylinder; and
a supply line configured to supply the sealant into the cylinder.

7. The apparatus of claim 1, wherein the sealant comprises an organic material.

8. An apparatus for manufacturing a semiconductor package, the apparatus comprising:
a chuck configured to support an object in a horizontal orientation and in a vertical orientation, apply suction to hold the object while in the vertical orientation, and rotate the object while in the vertical orientation, wherein the object comprises a wafer-to-wafer bonding structure, the wafer-to-wafer bonding structure comprises an edge area, and a gap is defined in the edge area between wafers; and
a supply structure configured to dispense a sealant to the gap of the wafer-to-wafer bonding structure held in the vertical orientation,
wherein the supply structure comprises:
a heating device configured to apply heat to the sealant on the wafer-to-wafer bonding structure while held in the vertical orientation;
a shaping device configured to apply pressure to the sealant on the wafer-to-wafer bonding structure while held in the vertical orientation; and
a cooling device configured to cool the sealant on the wafer-to-wafer bonding structure while held in the vertical orientation.

9. The apparatus of claim 8, wherein the supply structure further comprises a position sensor configured to identify a position of the gap of the wafer-to-wafer bonding structure.

10. The apparatus of claim 8, wherein the supply structure further comprises an optical sensor configured to identify a defect of the sealant on the wafer-to-wafer bonding structure.

11. The apparatus of claim 8, wherein the heating device comprises a laser.

12. The apparatus of claim 8, wherein the supply structure is further configured to dispense the sealant toward the gap of the rotating wafer-to-wafer bonding structure.

13. The apparatus of claim 8, wherein the cooling device is further configured to spray a cooling fluid.

14. The apparatus of claim 8, wherein the cooling device is further configured to cool the sealant on the rotating wafer-to-wafer bonding structure.

15. The apparatus of claim 8, further comprising a transfer structure configured to move the supply structure.

16. A method of manufacturing a semiconductor package, the method comprising:
applying suction to hold a wafer-to-wafer bonding structure in a vertical orientation, wherein the wafer-to-wafer bonding structure comprises an edge area, and a gap is defined in the edge area between wafers; and
filling the gap of the wafer-to-wafer bonding structure with a sealant while in the vertical orientation.

17. The method of claim 16, wherein the gap is recessed from an edge of each of the wafers.

18. The method of claim 16, further comprising:
inspecting the wafer-to-wafer bonding structure to determine whether a defect is present in the sealant;
applying heat to a position at which the defect is present based on determining the defect is present in the sealant;
additionally injecting the sealant to the position to which the heat is applied;
shaping the sealant that has been additionally injected; and
cooling the sealant that has been shaped.

19. The method of claim 18, wherein the inspecting comprises inspecting whether the sealant has a thickness that is a threshold value or more and whether a void is present in the sealant.

20. The method of claim 16, further comprising identifying a position of the gap of the wafer-to-wafer bonding structure held in the vertical orientation.
